(19) United States
(12) Patent Application Publication
(10) Pub. No.: US 2025/0191957 A1
(43) Pub. Date: Jun. 12, 2025

(54) HIGH CLAMP FORCE ELECTROSTATIC CHUCK FOR NON-FLAT SUBSTRATES

(71) Applicant: ENTEGRIS, INC., Billerica, MA (US)

(72) Inventors: Steven Donnell, Burlington, MA (US); Isaac J. Parker, Dover, NH (US); Caleb Minsky, Medfield, MA (US); Jakub Rybczynski, Arlington, MA (US)

(21) Appl. No.: 18/965,592

(22) Filed: Dec. 2, 2024

Related U.S. Application Data
(60) Provisional application No. 63/608,026, filed on Dec. 8, 2023.

(51) Int. Cl. H01L 21/683

(52) U.S. Cl. CPC H01L 21/6833

(57) ABSTRACT

An electrostatic chuck includes an electrode and a dielectric layer. When a voltage is applied to the electrode, the electrode is configured to generate an electrostatic force sufficient to flatten a non-flat substrate. The voltage applied to the electrode generates the electrostatic force sufficient to flatten the non-flat substrate such that a surface of the flattened substrate is substantially in contact with a surface of the electrostatic chuck.

### CROSS-REFERENCE TO RELATED APPLICATION

This application claims the benefit of and priority to U.S. Provisional Application No. 63/608,026, filed on Dec. 8, 2023, which is incorporated herein in its entirety for all purposes.

### FIELD

The present disclosure relates to electrostatic chucks and related methods.

### BACKGROUND

Electrostatic chucks are useful in the semiconductor manufacturing processes. During use of the electrostatic chuck, the back side of a substrate, such as bare wafer or an in-process semiconductor wafer, is held to the face of the electrostatic chuck by an electrostatic force sometimes referred to as a clamp force.

### SUMMARY

Some embodiments relate to an electrostatic chuck. In some embodiments, the electrostatic chuck comprises an electrode. In some embodiments, the electrostatic chuck comprises a dielectric layer located on the electrode. In some embodiments, when a voltage is applied to the electrode, the electrode is configured to generate an electrostatic force sufficient to at least partially flatten a non-flat substrate.

Some embodiments relate to a system. In some embodiments, the system comprises a non-flat substrate. In some embodiments, the system comprises an electrostatic chuck and a non-flat substrate disposed on the electrostatic chuck. In some embodiments, the electrostatic chuck comprises an electrode. In some embodiments, the electrostatic chuck comprises a dielectric layer located on the electrode. In some embodiments, at least the dielectric layer is located between the non-flat substrate and the electrode. In some embodiments, when a voltage is applied to the electrode, the electrode is configured to generate an electrostatic force sufficient to at least partially flatten the non-flat substrate.

Some embodiments relate to a method. In some embodiments, the method comprises arranging a non-flat substrate on an electrostatic chuck, the electrostatic chuck comprising an electrode layer and a dielectric layer located on the electrode layer and applying a voltage to the electrode sufficient to generate an electrostatic force that at least partially flattens the non-flat substrate.

### BRIEF DESCRIPTION OF THE DRAWINGS

To assist in understanding the present disclosure, reference is now made to the following description taken in conjunction with the accompanying drawings, in which:

FIG. 1 is a cross-sectional side view of a system 100 including an electrostatic chuck 102 and a substrate 104 on a surface of the electrostatic chuck, according to some embodiments.

FIG. 2 is a cross-sectional side view of an electrostatic chuck of FIG. 1, according to some embodiments.

FIG. 3 is a cross-sectional side view of a first layer and a dielectric layer of the electrostatic chuck of FIG. 1, according to some embodiments.

FIG. 4 is a top view of the electrostatic chuck of FIG. 1, according to some embodiments.

FIG. 5 is a flow diagram of a method for utilizing the electrostatic chuck of FIG. 1, according to some embodiments.

While the disclosure is amenable to various modifications and alternative forms, specifics thereof have been shown by way of example in the drawings and will be described in detail below. It is to be understood, however, that the intention is not to limit the disclosure to the embodiment(s) described. On the contrary, the disclosure is intended to cover all modifications, equivalents, and alternatives falling within the scope of the disclosure as defined by the appended claims.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Electrostatic chucks are electrical devices used for holding process substrates (e.g., wafers) in semiconductor manufacturing processes. The chucks hold the substrates onto their surface by utilizing an electric field generated by applying a voltage to the electrode located therein, to generate an electrostatic force acting on the substrate and clamping it to the surface of the chuck. Generally, this clamp force is dependent on a plurality of factors considered in electrostatic chuck design including, but not limited to, the electrical properties of the non-conductive material separating the clamped wafer from the electrodes-later referred to as a dielectric material, the applied voltage, a thickness of the dielectric material, the electrical properties of clamped wafer, the geometry of electrode layer, other like factors, or combinations thereof.

Commonly, wafer types may be made of either conductive or non-conductive materials. For example, monocrystalline silicon is a conductive material, i.e., a metal-like material with a significant free carrier content. During clamping of wafers made of conductive materials, a charge separation occurs in the wafer, thereby generating a clamp force due to charge attraction between the clamped substrate and the electrode layer. Non-conductive materials on the other hand do not exhibit mobile charges and rely on a different clamping mechanism-relying instead on much weaker dipole-to-dipole interactions from induced polarization in the non-conductive material due to fringing electric field at the electrode edges.

Typically, increasing the applied voltage at the electrode increases the clamp forces generated at the chuck. However, the clamp forces that can be generated in chucks is limited by the design of the electrode including the corresponding electrode pattern. To generate higher clamp forces, conventional chucks rely on designing the electrode layer in the chuck. For example, conventional chucks can be designed to generate certain higher clamp forces by increasing the area of the electrode pattern and/or by designing the electrode perimeter and spacing between neighboring electrodes of opposite polarity (electrode gap).

The voltage that can be applied to the electrode to generate the electrostatic force and thereby provide the clamp force is limited by the electrode design and the area of the electrode pattern. Because the electrode phases (i.e., traces) in the chuck are charged at high voltages and at opposite polarities to generate the desired clamp forces, conventional chucks include relatively wide gap electrode patterns (typically between 2 to 3 mm) to reduce a likelihood of electrical shorts occurring between the phases of opposing polarities. However, the wide gap electrode patterns in conventional chucks limits the area of the electrode, which thereby also limits the clamp force that can be generated in the conventional chucks.

Embodiments disclosed herein overcome at least the problems of conventional chucks by providing, among other things, electrostatic chucks that include a symmetrical electrode pattern, where the electrode phases (sometimes referred to as sections, regions, or traces) have the same area, width, length, and perimeter. This enables the electrostatic chucks to provide even clamp force distribution across the chuck surface.

At least another advantage of the electrostatic chucks disclosed herein according to the various embodiments is that the electrostatic chucks can include an increased area of the electrode pattern to provide improved clamp forces for substrates. For example, the electrostatic chucks may be capable of providing higher clamp forces for clamping process wafers made of conductive materials, non-conductive materials, or both when compared to conventional electrostatic chucks. In one or more embodiments, the electrostatic chucks can include a narrow gap electrode pattern, where neighboring phases (traces) of opposite polarity are spaced very close together, thereby effecting an increase in clamp force of the electrostatic chuck. Embodiments overcome at least the challenges of conventional chucks by providing electrostatic chucks that include narrow gap electrode patterns relative to the wider gap electrode patterns in conventional chucks, as will be further described herein. Higher clamp force is often desirable as it facilitates operating electrostatic chucks at higher backside gas pressure required to improve cooling efficiency of processed substrates. In addition, the higher clamp force allows for flattening of non-flat (e.g., bowed) substrates, where such a substrate is forced to flatten against the chuck's contact surface in response to the clamp force from the chuck.

At least another advantage of the electrostatic chucks disclosed herein is that the electrostatic chucks can include an electrode with minimized trace and gap width and a maximized electrode perimeter to fit longer traces within the same chucking area, which enables the electrostatic chucks to maintain a longer active clamp area by extending each phase's perimeter.

In accordance with an embodiment of the disclosure, the electrostatic chucks can include an insulating body, an electrode, and a dielectric layer. The electrostatic chuck may be configured to hold a wafer or workpiece (generically referred to herein as a “substrate”) during a manufacturing process performed on the workpiece. In some cases, the workpiece or substrate is an in-process wafer. To hold the substrate against a surface of the electrostatic chuck, a voltage is applied to the electrode to induce opposite polarity charges in the substrate and electrode, respectively, to provide a clamp force for holding the substrate on the surface of the chuck during the manufacturing process.

Some embodiments relate to an electrostatic chuck having an insulating body including one or more layers. In some embodiments, the insulating body may include a plurality of layers. The layers may be stacked on top of each other to define the insulating body. In some embodiments, the insulating body can further include one or more adhesive layers disposed between each of the plurality of layers to affix a layer to an adjacent layer. Each layer can be made of the same or substantially similar materials. In some embodiments, one or more layers can include one or more different materials than the other layers based on a desired characteristic of the electrostatic chuck.

Some embodiments relate to an electrostatic chuck having one or more electrodes. The electrodes can be disposed on a surface of the insulating body. In some embodiments, the electrodes may be embedded in the insulating body. In other embodiments, the electrodes may be partially embedded in the insulating body such that at least one portion of the electrode is exposed on the surface of the insulating body. The electrode(s) may be made of one or more electrically conductive materials capable of generating an electrostatic force as a result of voltage applied to the electrode(s).

Some embodiments relate to an electrostatic chuck having a plurality of electrodes each electrode having a distinct geometry and formed in a pattern on a surface of the insulating body. In some embodiments, the electrode pattern may be defined by at least one gap between adjacent phases of the electrode. A portion of an underlying substrate (e.g., insulating body) may be exposed through a gap in the electrode layer. Some embodiments of the electrode pattern may have a substantially symmetrical pattern defining a plurality of discrete sections or phases, where the phases have a substantially similar area, width, length, and perimeter as the other phases of the electrode pattern. Each section may be configured to have a polarity opposite an adjacent section. In this regard, when a voltage is applied to the electrode, the electrostatic force from the opposing polarities of corresponding adjacent phases provides the clamp force to hold the substrate against a surface of the electrostatic chuck. The gap or plurality of gaps in the electrostatic chuck may define two or more phases. For example, in some embodiments, a plurality of gaps may define six phases of the electrode pattern each phase having substantially the same area, width, length, and perimeter as the other phases. In some embodiments, the electrostatic chuck may include a plurality of gaps that define 2 to 12 phases, or any range or subrange therebetween. For example, in some embodiments, the gap or gaps may define 2 phases, 3 phases, 4 phases, 5 phases, 6 phases, 7 phases, 8 phases, 9 phases, 10 phases, 11 phases, 12 phases, or more than 12 phases, each section having substantially the same area, width, length, and perimeter as the other phases of the electrode pattern.

The width of a gap may be sufficiently narrow to facilitate use of the electrostatic chuck while limiting the risk of electrical failures. Narrowing the gap width results in increased electrode area and therefore increased clamp force of the electrostatic chuck. The gap or gaps defining the electrode pattern may have a width of 1 mm or less, or any range or subrange therebetween. In some embodiments, the gap or gaps may have a width ranging from 0.1 mm to 1 mm, 0.2 mm to 1 mm, 0.3 mm to 1 mm, 0.4 mm to 1 mm, 0.5 mm to 1 mm, 0.6 mm to 1 mm, 0.7 mm to 1 mm, 0.8 mm to 1 mm, 0.9 mm to 1 mm, 0.1 mm to 0.9 mm, 0.2 mm to 0.9 mm, 0.3 mm to 0.9 mm, 0.4 mm to 0.9 mm, 0.5 mm to 0.9 mm, 0.6 mm to 0.9 mm, 0.7 mm to 0.9 mm, 0.8 mm to 0.9 mm, 0.1 mm to 0.8 mm, 0.2 mm to 0.8 mm, 0.3 mm to 0.8 mm, 0.4 mm to 0.8 mm, 0.5 mm to 0.8 mm, 0.6 mm to 0.8 mm, 0.7 mm to 0.8 mm, 0.1 mm to 0.7 mm, 0.2 mm to 0.7 mm, 0.3 mm to 0.7 mm, 0.4 mm to 0.7 mm, 0.5 mm to 0.7 mm, 0.6 mm to 0.7 mm, 0.1 mm to 0.6 mm, 0.2 mm to 0.6 mm, 0.3 mm to 0.6 mm, 0.4 mm to 0.6 mm, 0.1 mm to 0.5 mm, 0.2 mm to 0.5 mm, 0.3 mm to 0.5 mm, 0.4 mm to 0.5 mm, 0.1 mm to 0.4 mm, 0.2 mm to 0.4 mm, 0.3 mm to 0.4 mm, 0.1 mm to 0.3 mm, 0.2 mm to 0.3 mm, 0.1 mm to 0.2 mm, or any range or subrange therebetween. In some embodiments, a gap or gaps defining the electrode pattern may have an average width of 1 mm or less, or any range or subrange therebetween. In one embodiment, the width of a gap or gaps defining the electrode pattern may have a width ranging from 0.5 mm to 0.7 mm. It is to be appreciated by those having ordinary skill in the art that the width of the gap or gaps may be dependent on the voltage configured to be applied to the electrostatic chuck. In addition, as the at least one gap may be filled with the dielectric material applied onto the electrode, it is also to be appreciated by those having ordinary skill in the art that the minimum width of the at least one gap may be based on the dielectric materials utilized in the electrostatic chucks.

Some embodiments relate to an electrostatic chuck including a dielectric material selected for having a certain voltage breakdown. In general, dielectric materials having higher purities provide higher voltage breakdowns when compared to those dielectric materials having lower purities. Dielectric materials having a high purity enable the spacing or gaps between the electrodes to be narrow as they can provide an improved voltage breakdown over those dielectric materials having a lesser impurity. The dielectric material can be selected based on its purity to provide an electrostatic chuck having a narrow band electrode pattern (i.e. narrow gap(s) between electrode phases), as described herein according to some embodiments. According to various embodiments, the selected dielectric material fills the gaps between the electrodes enabling the electrostatic chucks to operate at greater voltage ranges while reducing a risk of electrical failure of the chuck. Reducing the risk of electrical failure can prolong the lifetime of the dielectric layer and, as a result, the electrostatic chuck. Additionally, an electrostatic chuck having narrow gaps between electrode phases provides an improved clamp force relative to a conventional chuck having an electrode pattern with wide gaps between electrode phases.

Some embodiments relate to an electrostatic chuck having a dielectric layer with a thickness configured to maximize the clamp force. In some embodiments, the thickness of the dielectric layer may be configured to maintain a reasonable lifetime of the dielectric layer and the electrostatic chuck while enabling the electrostatic chucks to provide a certain clamp force. It is to be appreciated by those having ordinary skill in the art that a thickness of the dielectric layer affects the clamp forces provided by the chucks, and therefore a thinner dielectric layer may translate into higher clamp forces but with a tradeoff of being more fragile (both electrically and mechanically).

Some embodiments relate to an electrostatic chuck having a wafer contact surface with a certain resistivity, which enables effective clamping in a direct current (DC mode) at the electrostatic chuck while limiting a risk of electric field coupling occurring between the electrode and chuck surface coatings. In some embodiments, the contact surface has a high resistivity defined as a resistivity greater than 5×10¹² Ω m. The resistivity of the contact surface enables the electrostatic chucks to achieve maximum clamp force for a particular chuck design.

Some embodiments of the electrostatic chucks can have a polished wafer contact surface; the contact surface being polished so as to increase a contact area between the substrate and the electrostatic chuck. The contact surface can be polished by, for example, applying a surface grinder to smooth the peaks and valleys on the surface of the chuck to be more uniform. Increasing the contact area can also reduce leakage of heat transfer gas due to improved sealing between the backside of the substrate and the surface of the chuck. The contact surface may be configured to have an average surface roughness, Rₐ, within a certain range to allow the chuck to provide a certain clamp force, that is, the clamp force provided by the chuck may be based on the average surface roughness of the electrostatic chuck. In this regard, lowering the roughness of the surface of the chuck can increase the clamp force for a given applied voltage.

The surface roughness, Rₐ, of the contact surface may be in a range that facilitates an optimal clamp force at the chuck for a given applied voltage. The surface roughness, Rₐ, of the contact surface may be 0.5 micrometers (μm) or less, or any range or subrange therebetween. In some embodiments, the surface roughness, Rₐ, of the contact surface may range from 0.05 to 0.5 μm, 0.05 to 0.4 μm, 0.05 to 0.3 μm, 0.05 to 0.02 μm, 0.05 to 0.2 μm, 0.05 to 0.1 μm, 0.05 to 0.09 μm, 0.05 to 0.08 μm, or any range or subrange therebetween. Some embodiments relate to an electrostatic chuck having a surface coating located on the dielectric layer, the surface coating forming the contact surface configured to contact a backside of the substrate and having average surface roughness, Rₐ, within the certain parameter in accordance with the disclosure.

Some embodiments relate to an electrostatic chuck that can be utilized to support and retain a position of a substrate in a manufacturing process based on the application of a voltage to the one or more electrodes in the electrostatic chuck. Exemplary substrates include bare and in-process silicon wafers and bare and in-process silicon carbide wafers but are not limited to these. In some embodiments, the substrate may be a non-flat substrate, that is, the substrate may have one or more curved portions. For example, a non-flat substrate that an electrostatic chuck, as described herein, may be configured to clamp for a manufacturing process may be convex such that a center portion bows outward and away from the contact surface of the electrostatic chuck. For example, in some embodiments, the non-flat substrate can be convex such that a center portion is bowed outward and away from an upper surface of an electrostatic chuck by a distance of 400 μm or less. In other embodiments, a non-flat substrate can be concave such that an edge portion of the non-flat substrate is elevated relative to a center portion of the non-flat substrate. When a voltage is applied to the electrode in the electrostatic chuck, the electrode may be configured to generate an electrostatic force sufficient to clamp the non-flat substrate onto a surface of the electrostatic chuck. In some embodiments, when the voltage is applied to the electrode, the electrostatic force may be sufficient to at least partially flatten the non-flat substrate on to the surface of the electrostatic chuck. As used herein, the term “flatten” refers to any change in a shape of a substrate. In some embodiments, the term “flatten” results in increasing a surface area of the non-flat substrate that directly contacts the surface of the electrostatic chuck. For example, in the absence of an applied voltage, X % of a bottom surface area of the substrate may directly contact the upper surface of electrostatic chuck (i.e. the contact surface); whereas under an applied voltage, Y % of a bottom surface area of the non-flat substrate directly contacts the electrostatic chuck, where Y is greater than X. In some embodiments, the voltage applied to the electrode generates an electrostatic force sufficient to flatten the non-flat substrate such that a substantial portion of a bottom surface area of the flattened substrate is in contact with an upper surface area (the contact surface) of the electrostatic chuck.

The X % of surface area of the non-flat substrate may range from 1% to 99%, or any range or subrange between 1% and 99%. In some embodiments, for example, X % of surface area is 1% to 90%, 1% to 80%, 1% to 70%, 1% to 60%, 1% to 50%, 1% to 40%, 1% to 30%, 1% to 20%, 1% to 10%, 10% to 99%, 20% to 99%, 30% to 99%, 40% to 99%, 50% to 99%, 60% to 99%, 70% to 99%, 80% to 99%, or 90% to 99%.

The Y % of surface area of the non-flat substrate may range from 2% to 100%, or any range or subrange between 2% and 100%. In some embodiments, for example, Y % of surface area is 2% to 90%, 2% to 80%, 2% to 70%, 2% to 60%, 2% to 50%, 2% to 40%, 2% to 30%, 2% to 20%, 2% to 10%, 10% to 100%, 20% to 100%, 30% to 100%, 40% to 100%, 50% to 100%, 60% to 100%, 70% to 100%, 80% to 100%, or 90% to 100%.

The voltage applied to the electrode(s) of the electrostatic chuck, as described herein, may be sufficient to achieve a desired Y % of surface area of the substrate directly contacting the electrostatic chuck. The voltage may range from 1 V to 5000 V, or any range or subrange between 1 V and 5000 V. For example, in some embodiments, the voltage can range from 1 V to 4500 V, 1 V to 4000 V, 1 V to 3500 V, 1 V to 3000 V, 1 V to 2500 V, 1 V to 2000 V, 1 V to 1500 V, 1 V to 1000 V, 1 V to 500 V, 1 V to 50 V, 1 V to 10 V, 500 V to 5000 V, 1000 V to 5000 V, 1500 V to 5000 V, 2000 V to 5000 V, 2500 V to 5000 V, 3000 V to 5000 V, 3500 V to 5000 V, 4000 V to 5000 V, or 4500 V to 5000 V.

In this regard, the one or more embodiments described herein relate to an electrostatic chuck having one or more components adjacent to a contact surface of the chuck that may be configured to generate as high of a clamp force as possible at the electrostatic chuck for a given applied voltage. High clamp forces are often desirable as they allow for operating electrostatic chucks at higher backside gas pressures, which can provide improved cooling efficiency of processed substrates. In addition, the higher clamp forces provided by the electrostatic chucks, as described herein according to the various embodiments, also facilitate flattening of bowed substrates when a voltage is applied to hold the substrate in position for a manufacturing process, where the substrate is forced to flatten against the chuck's contact surface. For example, the clamp force of the electrostatic chuck may be 14 Torr or more at an applied voltage of 2500 V. In another example, the clamp force of the electrostatic chuck may be 30 Torr at an applied voltage 2750 V.

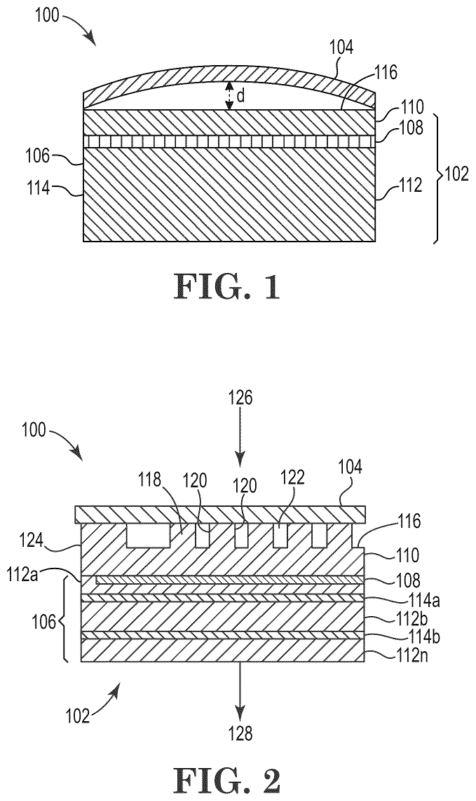

FIG. 1 is a cross-sectional side view illustrating a system 100 including an electrostatic chuck 102 and a substrate 104 (e.g., a bare or in-process wafer) arranged on a surface of the electrostatic chuck, according to some embodiments. The electrostatic chuck 102 includes an insulating body 106, an electrode layer 108 including one or more electrodes, and a dielectric layer 110. The insulating body 106 may be a single layer 112. In some embodiments, the insulating body 106 may have at least one layer 112. In other embodiments, the insulating body 106 may have a plurality of layers 112, as will be further described herein.

The electrostatic chuck 102 includes the electrode layer 108. In some embodiments, the electrode layer 108 may be formed on a surface of the insulating body 106 adjacent to the contact surface 116 of the electrostatic chuck 102. The electrostatic chuck 102 includes the dielectric layer 110 located on the electrode layer 108. In some embodiments, the dielectric layer 110 directly contacts the electrode layer 108. In addition, some embodiments of the dielectric layer 110 may be configured to fill any gaps defining the electrode pattern, as will be further described herein.

The substrate 104 may be a non-flat substrate. In some embodiments, the substrate 104 may have one or more curved portions such that it is either convex or concave, as described herein. In FIG. 1, the substrate 104 is convex such that when arranged on a contact surface 116, a central portion of the substrate 104 is bowed or curved outward and away from the contact surface 116 by a distance, d, relative at least one edge of the substrate 104. For example, the non-flat substrate may be bowed by 400 μm or less. In some embodiments, the non-flat substrate 104 may be a bare or an in-process silicon wafer or a bare or in-process silicon carbide wafer. However, it is to be appreciated by those having ordinary skill in the art that the types of substrates that may be processed utilizing the one or more embodiments of the electrostatic chuck 102 described herein are not intended to be limited may also include other substrates, workpieces, wafers, and the like, where applying the voltage to the electrode layer 108 generates an electrostatic force that provides the clamp force to hold the substrate or other object on the surface of the electrostatic chuck 102 for processing.

When voltage is not being applied to the electrostatic chuck 102 such as, for example, in FIG. 1, the substrate 104 may adopt the shape of a non-flat substrate having a convex shape or a concave shape relative the contact surface 116 of the electrostatic chuck 102. As used herein, the term “convex” refers to where aa central portion of the substrate is higher relative to at least one edge of the substrate when the substrate is positioned onto the electrostatic chuck such that a backside of the substrate is facing a contact surface of the electrostatic chuck. As used herein, the term “concave” refers to where a center (e.g., central portion) of the substrate is lower relative to at least one edge of the workpiece when the workpiece is positioned onto the electrostatic chuck such that a backside of an edge portion the workpiece is facing a contact surface of the electrostatic chuck.

When a voltage is applied to the electrode layer 108 the electrode layer 108 can generate an electrostatic force sufficient to clamp the substrate 104 onto the contact surface 116 of the electrostatic chuck. In some embodiments, when the voltage is applied to the electrode layer 108, the electrostatic force may be sufficient to flatten the non-flat substrate 104, as depicted in FIG. 2. As used herein, the term “flatten” refers to any change in a shape of a substrate. In some embodiments, the term “flatten” results in increasing a surface area of the non-flat substrate 104 that directly contacts the surface 116 of the electrostatic chuck 102. For example, in the absence of an applied voltage, X% of a surface area of the substrate 104 may directly contact the electrostatic chuck 102; whereas under an applied voltage, Y% of a surface area of the non-flat substrate 104 directly contacts the electrostatic chuck 102, where Y is greater than X. In some embodiments, the voltage applied to the electrode layer 108 generates an electrostatic force sufficient to flatten the non-flat substrate such that a substantial portion of a surface of the flattened substrate 104 is in contact with a contact surface 116 of the electrostatic chuck 102. In this regard, the insulating body 106, electrode layer 108, dielectric layer 110, and one or more other components of the electrostatic chuck 102 may be configured to generate as high of a clamp force as possible at the electrostatic chuck 102 for a given applied voltage to allow for operating the electrostatic chuck 102 at higher backside gas pressures, which provides improved cooling efficiency of a processed substrate. In addition, the higher clamp forces provided by the electrostatic chuck 102 also facilitates flattening of bowed substrates such as, for example substrate 104, when a voltage is applied to hold substrate 104 in position for a manufacturing process, where such substrate 104 is forced to flatten against the contact surface 116 of the electrostatic chuck 102, as shown in FIG. 2.

FIG. 2 is a cross-sectional side view of electrostatic chuck 102 of FIG. 1, according to some embodiments. The insulating body 106 of electrostatic chuck 102 may include more than one layer 112. For example, in some embodiments, the insulating body 106 may include two layers, three layers, or four or more layers. In FIG. 2, the insulating body 106 is shown having layer 112a, 112b, through 112n, hereinafter referred to collectively as layers 112. In addition, the electrostatic chuck 102 may include adhesive layers 114a, 114b arranged between adjacent layers 112, the adhesive layers 114a, 114b being configured to affix adjacent layers 112 to each other or to enable another component to be arranged between layers 112.

The contact surface 116 of electrostatic chuck 102 may include a plurality of protrusions 118. The top surface of protrusions 118 contact the back side of a substrate 104 and, by their support of the substrate 104, provide uniform loading and reduced levels of particles correlated with the protrusions 118. The protrusions 118 have side walls 120 and are separated by gaps 122.

Some embodiments of the electrostatic chuck 102 include a dielectric layer 110 that may have protrusions 118 formed in it. Alternatively, the protrusions 118 may be formed in one or more layers of material disposed on the surface of the dielectric layer 110. Although not shown in the figures, in some embodiments, electrostatic chuck 102 may have a surface coating applied onto the dielectric layer 110 that forms the contact surface 116. In some embodiments, the protrusions 118 may be formed on the one or more layers of the surface coating.

Referring to FIG. 2, one or more electrodes 108 are formed in a first layer 112a, which is covered by the dielectric layer 110. Beneath the first layer 112a are a first adhesive layer 114a, a second layer 112b, an optional second adhesive layer 114b, and a bottom layer 112n. In some embodiments, the layer 112n may, for example, contact a cooling fluid, such as water. In some embodiments, the dielectric layer 110 includes a gas seal annular ring 124 formed in its periphery. Process energy may be received by the substrate as indicated by arrow 126; and energy is removed as indicated by arrow 128.

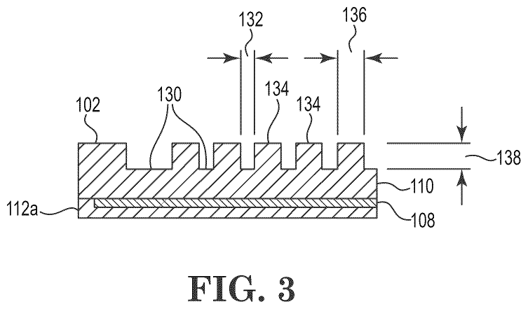

FIG. 3 is a cross-sectional side view of a first layer 112a and a dielectric layer 110 of the electrostatic chuck 102 of FIG. 1, according to some embodiments.

An electrode 108 is embedded in the first layer 112a which is covered by the dielectric layer 110. The dielectric layer 110 includes protrusions 118. The features and dimensions of the protrusions 118 and dielectric layer 110 include a channel or gap surface bottom 130, a gap spacing 132, a protrusion top surface 134, a protrusion width or area 136, and a protrusion height 138.

The protrusions 118 may be any regularly or irregularly shaped three dimensional protrusion and may be disposed in any regular geometric or other pattern that substantially equally distributes force to the substrate 104 and reduces particles due to uneven loading between the substrate 104 and protrusions 118. Each protrusion 118 may have a cylindrical side or a plurality of sides and a top. The edges of the protrusions may be square, as in the embodiment of FIG. 2, or may be contoured to help distribute the load between the substrate 104 and electrostatic chuck 102.

In some embodiments, the electrostatic chuck 102 may further include a surface coating located on the dielectric layer 110. The surface coating may have an average surface roughness, Rₐ, of 0.5 micrometers (μm) or less. In some embodiments, the surface coating may have an average surface roughness, Rₐ, ranging from 0.05 to 0.5 μm, 0.05 to 0.4 μm, 0.05 to 0.3 μm, 0.05 to 0.02 μm, 0.05 to 0.2 μm, 0.05 to 0.1 μm, 0.05 to 0.09 μm, 0.05 to 0.08 μm, or any range or subrange therebetween.

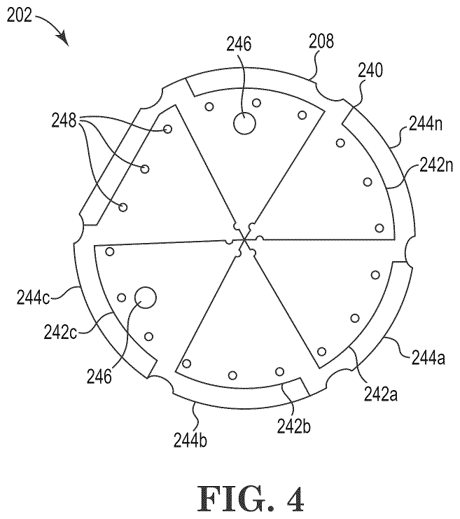

FIG. 4 is a top sectional view of a non-limiting example of an electrostatic chuck 202, according to some embodiments. The electrostatic chuck 202 includes an electrode 208 formed on a surface of an insulating body (not visible), the electrode 208 may have an electrode pattern such as, for example, the electrode pattern 240 as shown in FIG. 4.

In the electrostatic chuck 202, the electrode pattern 240 may be defined by at least one gap such as gap 242a, 242b, and 242c (collectively referred to herein as gaps 242). In the example provided, the gaps 242 define one or more phases 244a, 244b, and 244c (collectively referred to herein as phases 244), the phases 244 having similar or substantially similar proportions as each other.

Some embodiments of the electrostatic chuck 202 may include multiple electrodes 208, and the electrode pattern 240 may form discrete regions for each phase, the regions being defined by the phases 244, and each electrode 208 may be arranged in a corresponding discrete region such as to form a distinctive electrode pattern 240 for generating the electrostatic force in the electrostatic chuck 202 for providing higher clamp forces for holding substrates during a manufacturing process at a given applied voltage. It is to be appreciated by those having ordinary skill in the art that the arrangement of each of the discrete phases 244 of the electrode 208 is not intended to be limiting and may therefore be arranged in any of a plurality of different patterns that allows the electrostatic chuck to generate an electrostatic force to provide high clamp forces for clamping substrates (e.g., flat substrates, non-flat substrates, or both) that may be made of different types of materials (e.g., conductive materials, non-conductive materials, or both) to the electrostatic chuck and for performing manufacturing processes that may necessitate higher backside gas pressures.

It is to be appreciated by those having ordinary skill in the art that although FIG. 4 shows electrode 208 having six phases 244, FIG. 4 is not intended to be limiting, and therefore electrode 208 may include more or less phases based on the clamping characteristics desired at the electrostatic chuck 202 such as, for example, based on the characteristics of the substrate being processed and/or based on the manufacturing processes applied to the substrate.

In the electrostatic chuck 202, a width of the gaps 242 that define the electrode pattern 240 may be within a certain range based on one or more factors including, but not limited to, area of the electrode 208, clamp force for a certain applied voltage, dielectric materials in the dielectric layer, sealing characteristics between the surface of the electrostatic chuck 202 and the substrate, other factors, or any combinations thereof. In this regard, having a narrow gap width allows for a larger electrode pattern 240 in the electrostatic chuck 202, which thereby allows the electrostatic chuck 202 to provide improved clamp forces for a given voltage applied to the electrode 208. That is the narrow gap width allows for providing higher clamp forces without necessitating increased voltages applied to the electrode 208. In some embodiments, the gaps 242 may be 1 mm or less in width. In other embodiments, the gaps 242 may have an average width of 1 mm or less. In one or more embodiments, the gaps may be within a range from 0.5 mm to 0.7 mm in width.

Some embodiments of the electrode may be configured such that each phase has an opposite polarity from other adjacent phases when voltage is applied to the electrode. For example, in FIG. 4, phase 244b may have a negative polarity and phase 244a and phase 244c may both have a positive polarity when a voltage is applied so that adjacent phases (e.g., 244a and 244b or 244b and 244c) have opposite polarities to enable the electrostatic chuck 202 to generate the electrostatic force.

Some embodiments of the electrostatic chuck 202 may include one or more channels 246 extending through the electrostatic chuck 202 including the insulating body, the electrode, the dielectric layer (not shown), other components of the electrostatic chuck 202, or any combinations thereof. The one or more channels 246 may form corresponding gas openings 248 arranged across a surface 216 of the electrostatic chuck 202. The gas openings 248 may be configured, for example, to allow a heat transfer gas to be applied to the backside of a substrate during the manufacturing processes. In this regard, the one or more embodiments of the electrostatic chucks disclosed herein having a larger electrode pattern such as, for example, electrode pattern 240 allows for operating the electrostatic chucks at higher backside gas pressures for improving cooling efficiency of the processing substrate of the substrate.

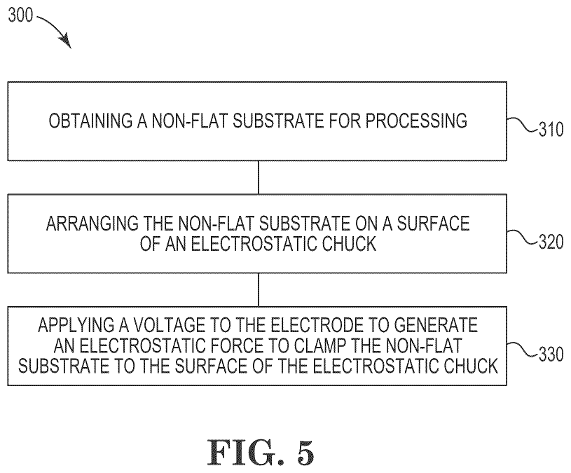

FIG. 5 is a flow diagram of a method 300 for utilizing the electrostatic chuck 102 of FIG. 1, according to some embodiments. As shown in FIG. 5, the method 300 for utilizing the electrostatic chuck 102 to clamp a non-flat substrate may include one or more of the following steps: a step 310 of obtaining a non-flat substrate for processing, a step 320 of arranging the non-flat substrate on a surface of an electrostatic chuck, the electrostatic chuck comprising an electrode and a dielectric layer located on the electrode, and a step 330 of applying a voltage to the electrode to generate an electrostatic force to clamp the non-flat substrate to the surface of the electrostatic chuck. In some embodiments, the electrostatic force generated by applying the voltage to the electrode may be sufficient to flatten the non-flat substrate such that a surface of the flattened substrate is substantially in contact with the surface of the electrostatic chuck.

At step 310, the method 300 may comprise obtaining a non-flat substrate for processing. The non-flat substrate may have one or more curved portions. In some embodiments, the non-flat substrate may have a bowed central portion such that the substrate has a convex shape. In other embodiments, the non-flat substrate may have a concave shape.

At step 320, the method 300 may comprise arranging the non-flat substrate on a surface of an electrostatic chuck, the electrostatic chuck comprising an electrode and a dielectric layer located on the electrode. In some embodiments, the dielectric layer may define the contact surface of the electrostatic chuck. The electrostatic chuck may further include a surface coating applied onto the dielectric layer. In some embodiments, the surface coating may define the contact surface of the electrostatic chuck.

At step 330, the method 300 may include applying a voltage to the electrode to generate an electrostatic force to clamp the non-flat substrate to the surface of the electrostatic chuck. The electrostatic force generated by applying the voltage to the electrode is sufficient to flatten the non-flat substrate such that a surface of the flattened substrate is directly in contact with the surface of the electrostatic chuck. In some embodiments, the electrostatic force generated by applying the voltage to the electrode is sufficient to flatten the non-flat substrate such that a surface of the flattened substrate substantially contacts with the surface of the electrostatic chuck. In other embodiments, the electrostatic force generated by applying the voltage to the electrode is sufficient to flatten the non-flat substrate such that a greater proportion of a surface of the substrate is directly in contact with a surface of the electrostatic chuck as compared to a proportion of a surface of the substrate is directly in contact with the surface of the electrostatic chuck when the voltage is not applied to the electrode. That is, for non-flat substrates, the bowed feature of the non-flat substrate prevents the substrate from lying flat onto the contact surface of the electrostatic chuck for processing, and therefore the electrostatic chuck of the one or more embodiments of the present disclosure have one or more features such as, for example, an electrode with an enlarged area of the electrode pattern, which enables providing high clamp forces sufficient to flatten the non-flat substrate for a given applied voltage. In some embodiments, the non-flat substrate may have of bow of 400 μm or less, and the electrostatic chuck may be capable of providing sufficiently high clamp forces to flatten the substrate to the surface of the electrostatic chuck in response to a given applied voltage.

### Aspects

Aspect 1. An electrostatic chuck comprising:
an electrode; and
a dielectric layer located on the electrode;
   wherein, when a voltage is applied to the electrode, the electrode is configured to generate an electrostatic force sufficient to at least partially flatten a non-flat substrate.

Aspect 2. The electrostatic chuck according to Aspect 1, wherein the voltage applied to the electrode is configured to generate the electrostatic force sufficient to flatten the non-flat substrate such that a surface of the flattened substrate is substantially in contact with a surface of the electrostatic chuck.

Aspect 3. The electrostatic chuck according to any one of Aspects 1-2, wherein the electrode defines at least one gap through which at least a portion of a substrate is exposed,
wherein the at least one gap has a width of 1 mm or less.

Aspect 4. The electrostatic chuck according to Aspect 3, wherein the width of the at least one gap comprises a range from 0.1 mm to 1 mm.

Aspect 5. The electrostatic chuck according to Aspect 3, wherein the dielectric layer directly contacts the electrode.

Aspect 6. The electrostatic chuck according to any one of Aspects 1-5, further comprising:
a surface coating located on the dielectric layer.

Aspect 7. The electrostatic chuck according to Aspect 6, wherein the surface coating has an average surface roughness, Rₐ, of 0.5 μm or less.

Aspect 8. The electrostatic chuck according to any one of Aspects 1-7, wherein the electrostatic chuck has a surface coating having an average surface roughness, Rₐ, of 0.05 μm to 0.5 μm.

Aspect 9. The electrostatic chuck according to any one of Aspects 1-8, wherein the non-flat substrate is an in-process wafer.

Aspect 10. The electrostatic chuck according to any one of Aspects 1-9, wherein, when the voltage is not applied to the electrode, the non-flat substrate has a convex shape.

Aspect 11. The electrostatic chuck according to any one of Aspects 1-10, wherein, when the voltage is not applied to the electrode, the non-flat substrate has a concave shape.

Aspect 12. A system comprising:
a non-flat substrate; and
an electrostatic chuck comprising:
   an electrode; and
   a dielectric layer located on the electrode;
   wherein at least the dielectric layer is located between the non-flat substrate and the electrode;
   wherein, when a voltage is applied to the electrode, the electrode is configured to generate an electrostatic force sufficient to at least partially flatten the non-flat substrate.

Aspect 13. The system according to Aspect 12, wherein the electrode defines at least one gap through which at least a portion of a substrate is exposed;
wherein the at least one gap has a width of 1 mm or less.

Aspect 14. The system according to Aspect 13, wherein the width of the at least one gap comprises a range from 0.1 mm to 1 mm.

Aspect 15. The system according to Aspect 13, wherein the dielectric layer directly contacts the electrode.

Aspect 16. The system according to any one of Aspects 12-15, further comprising:
a surface coating located on the dielectric layer.

Aspect 17. The system according to Aspect 16, wherein the surface coating has an average surface roughness, Rₐ, of 0.5 μm or less.

Aspect 18. The system according to any one of Aspects 12-17, wherein, when the voltage is not applied at the electrode, the non-flat substrate has a convex shape.

Aspect 19. The system according to any one of Aspects 12-18, wherein, when the voltage is not applied at the electrode, the non-flat substrate has a concave shape.

Aspect 20. A method comprising:
obtaining a non-flat substrate;
arranging the non-flat substrate on an electrostatic chuck, the electrostatic chuck comprising an electrode and a dielectric layer located on the electrode; and
applying a voltage to the electrode sufficient to generate an electrostatic force that at least partially flattens the non-flat substrate.

All prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Accordingly, in any one or more of the embodiments disclosed herein, a particular structural component being disposed between two other structural elements can be:
disposed directly between both of the two other structural elements such that the particular structural component is in direct contact with both of the two other structural elements;
disposed directly next to only one of the two other structural elements such that the particular structural component is in direct contact with only one of the two other structural elements;
disposed indirectly next to only one of the two other structural elements such that the particular structural component is not in direct contact with only one of the two other structural elements, and there is another element which is disposed between the particular structural component and the one of the two other structural elements;
disposed indirectly between both of the two other structural elements such that the particular structural component is not in direct contact with both of the two other structural elements, and other features can be disposed therebetween; or any combination(s) thereof.

What is claimed is:

1. An electrostatic chuck comprising:
an electrode; and
a dielectric layer located on the electrode;
wherein, when a voltage is applied to the electrode, the electrode is configured to generate an electrostatic force sufficient to at least partially flatten a non-flat substrate.

2. The electrostatic chuck of claim 1, wherein the voltage applied to the electrode is configured to generate the electrostatic force sufficient to flatten the non-flat substrate such that a surface of the flattened substrate is substantially in contact with a surface of the electrostatic chuck.

3. The electrostatic chuck of claim 1, wherein the electrode defines at least one gap through which at least a portion of a substrate is exposed,
wherein the at least one gap has a width of 1 mm or less.

4. The electrostatic chuck of claim 3, wherein the width of the at least one gap comprises a range from 0.1 mm to 1 mm.

5. The electrostatic chuck of claim 3, wherein the dielectric layer directly contacts the electrode.

6. The electrostatic chuck of claim 1, further comprising:
a surface coating located on the dielectric layer.

7. The electrostatic chuck of claim 6, wherein the surface coating has an average surface roughness, Rₐ, of 0.5 μm or less.

8. The electrostatic chuck of claim 1, wherein the electrostatic chuck has a surface coating having an average surface roughness, Rₐ, of 0.05 to 0.5 μm.

9. The electrostatic chuck of claim 1, wherein the non-flat substrate comprises an in-process wafer.

10. The electrostatic chuck of claim 1, wherein, when the voltage is not applied to the electrode, the non-flat substrate has a convex shape.

11. The electrostatic chuck of claim 1, wherein, when the voltage is not applied to the electrode, the non-flat substrate has a concave shape.

12. A system comprising:
a non-flat substrate; and
an electrostatic chuck comprising:
an electrode; and
a dielectric layer located on the electrode;
wherein at least the dielectric layer is located between the non-flat substrate and the electrode;
wherein, when a voltage is applied to the electrode, the electrode is configured to generate an electrostatic force sufficient to at least partially flatten the non-flat substrate.

13. The system of claim 12, wherein the electrode defines at least one gap through which at least a portion of a substrate is exposed;
wherein the at least one gap has a width of 1 mm or less.

14. The system of claim 13, wherein the width of the at least one gap comprises a range from 0.1 mm to 1 mm.

15. The system of claim 13, wherein the dielectric layer directly contacts the electrode.

16. The system of claim 12, further comprising:
a surface coating located on the dielectric layer.

17. The system of claim 16, wherein the surface coating has an average surface roughness, Rₐ, of 0.05 μm or less.

18. The system of claim 12, wherein, when the voltage is not applied at the electrode, the non-flat substrate has a convex shape.

19. The system of claim 12, wherein, when the voltage is not applied at the electrode, the non-flat substrate has a concave shape.

20. A method comprising:
arranging a non-flat substrate on an electrostatic chuck, the electrostatic chuck comprising an electrode and a dielectric layer located on the electrode; and
applying a voltage to the electrode sufficient to generate an electrostatic force that at least partially flattens the non-flat substrate.
